(19) United States
(12) Patent Application Publication
(10) Pub. No.: US 2025/0311090 A1
(43) Pub. Date: Oct. 2, 2025

(54) METHODS, SYSTEMS, APPARATUS, AND ARTICLES OF MANUFACTURE TO REDUCE CROSSTALK IN INTEGRATED CIRCUIT PACKAGES

(71) Applicant: Intel Corporation, Santa Clara, CA (US)

(72) Inventors: Shaohua Li, Pleasanton, CA (US); Carlos Alberto Lizalde Moreno, Guadalajara (MX); Kai Xiao, Portland, OR (US); Raul Enriquez Shibayama, Zapopan (MX); Vijaya Kumar Boddu, Pleasanton, CA (US); Sri Chaitra Jyotsna Chavali, Gilbert, AZ (US); Mo Liu, Scotts Valley, CA (US)

(21) Appl. No.: 18/617,370

(22) Filed: Mar. 26, 2024

(51) Int. Cl. H05K 1/02; H01L 23/00; H01L 23/498; H01L 23/538; H01L 25/065; H05K 1/11

(52) U.S. Cl. CPC H05K 1/0222; H01L 23/49816; H01L 23/5381; H01L 24/08; H01L 24/16; H01L 25/0652; H05K 1/115; H01L 2224/08146; H01L 2224/08155; H01L 2224/16104; H01L 2224/16225; H01L 2924/1431; H01L 2924/1434; H01L 2924/15311; H01L 2924/30105; H01L 2924/3025

(57) ABSTRACT

Methods, systems, apparatus, and articles of manufacture to reduce crosstalk in integrated circuit packages are disclosed. An example apparatus includes a package substrate, a conductive via extending between first and second surfaces of the package substrate, a metal casing extending between the first and second surfaces, the metal casing surrounding the conductive via, and a dielectric material positioned between the conductive via and the metal casing.

### FIELD OF THE DISCLOSURE

This disclosure relates generally to integrated circuit packages and, more particularly, to methods, systems, apparatus, and articles of manufacture to reduce crosstalk in integrated circuit packages.

### BACKGROUND

In many integrated circuit (IC) packages, one or more semiconductor dies are mechanically and electrically coupled to an underlying package substrate. In many cases, such package substrates include a package core that provides structural integrity to the package substrate. Some package substrates include one or more vias (e.g., openings or holes) extending through the package core to electrically couple devices on a first side of the semiconductor dies to an array of contacts (e.g., bumps, pads) on a second side of the semiconductor dies. A first portion of the vias can be used to transmit electrical signals between the first and second sides of the semiconductor dies, and a second portion of the vias can be used for grounding of the electrical signals.

### BRIEF DESCRIPTION OF THE DRAWINGS

FIG. 1 illustrates an example integrated circuit (IC) package on a printed circuit board (PCB).

FIG. 2 illustrates an example grounding plated through-hole (PTH) that may be implemented in the example IC package of FIG. 1.

FIG. 3 is a side view of the example grounding PTH of FIG. 2.

FIG. 4 is a top view of the example grounding PTH of FIGS. 2 and/or 3.

FIG. 5A is a top view of the example package substrate of the example IC package of FIG. 1 implementing an array of the example grounding PTH of FIGS. 2, 3, and/or 4.

FIG. 5B is a top view of a second package substrate not including the grounding PTHs of FIG. 5A.

FIG. 6 is a cross-sectional side view of an example package substrate including the example grounding PTH of FIGS. 2, 3, 4, and/or 5A.

FIG. 7A is a cross-sectional view of an example core that may be implemented in the example IC package of FIG. 1.

FIG. 7B illustrates the example core of FIG. 7A with example foil removed and/or reduced.

FIG. 7C illustrates the example core of FIGS. 7A and/or 7B with a first example metal layer provided on one or more surfaces of the core.

FIG. 7D illustrates the example core of FIGS. 7A, 7B, and/or 7C with portions of the first metal layer removed.

FIG. 7E illustrates the example core of FIGS. 7A, 7B, 7C, and/or 7D including first and second example dielectric layers on the first and second example core surfaces of the core, respectively.

FIG. 7F illustrates the example core of FIGS. 7A, 7B, 7C, 7D, and/or 7E including one or more example openings in the example dielectric material.

FIG. 7G illustrates an example signal PTH provided in the example dielectric material in the example grounding PTH of FIGS. 7C, 7D, 7E, and/or 7F.

FIG. 7H illustrates the example signal PTH of FIG. 7G including example non-conductive material positioned in the signal PTH.

FIG. 7I illustrates example contact pads coupled to the signal PTH and example via pads coupled to respective ones of the grounding members.

FIG. 8 is a flowchart representative of an example method of manufacturing the example package substrate of FIGS. 1 and/or 6 including the example grounding PTH of FIGS. 2, 3, 4, 5A, and/or 6.

FIG. 9 is a top view of a wafer including dies that may be included in an IC package constructed in accordance with teachings disclosed herein.

FIG. 10 is a cross-sectional side view of an IC device that may be included in an IC package constructed in accordance with teachings disclosed herein.

FIG. 11 is a cross-sectional side view of an IC device assembly that may include an IC package constructed in accordance with teachings disclosed herein.

FIG. 12 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

In many integrated circuit (IC) packages, a package substrate includes a core (e.g., a package core) that provides structural integrity to the package substrate. In some cases, the package substrate includes one or more vias (e.g., openings, holes, plated through-holes (PTHs)) extending through the core to form electrical paths between the two or more locations and/or devices (e.g., between a printed circuit board (PCB) on a first side of the package substrate and a semiconductor die on a second side of the package substrate). As a result, electrical signals can pass between the two or more locations (e.g., between the die and the PCB) through the vias. In some cases, a first portion of the vias (e.g., signal vias, signal PTHs) are used for signal routing, while a second portion of the vias are used for providing power to one or more devices coupled to the package substrate. Further, a third portion of the vias can be designated as ground vias to provide a return path for the electrical signals to the ground. In some cases, the ones of the signal vias can be arranged in pairs (e.g., differential pairs) to enable differential signaling.

A need for increased connectivity and input/output speeds of IC packages continues to motivate efforts directed to increasing the number of signal vias that can be implemented in the package substrate. In some cases, by increasing the number of signal vias, speed and/or bandwidth of information travel through the signal vias can be increased. In some cases, increasing the number of vias that can be fabricated in a package substrate depends on increasing a surface area (e.g., an input/output (I/O) area) of the core of the package substrate and/or reducing a pitch (e.g., a bump-to-bump pitch) of the vias. However, increasing the surface area of the core increases manufacturing and/or parts costs associated with the IC package, and/or increases the lengths of traces to be implemented in the package substrate, thus reducing efficiency of power and/or signal transmission through the traces. In some cases, the number of vias fabricated in the package substrate can be increased by reducing the pitch of the vias. However, reducing the pitch may result in increased crosstalk between the vias, thus reducing quality of signals passing therethrough. Typically, to reduce pitch of the vias while reducing crosstalk, additional ones of the vias may be designated as ground vias (e.g., instead of signal routing vias). However, increasing a proportion of the vias designated as ground vias may reduce the bandwidth of information travel through the vias.

Examples disclosed herein reduce crosstalk between vias while improving signaling bandwidth of an IC package. In particular, examples disclosed herein provide an example grounding PTH (e.g., a casing, a metal casing, etc.) in an example IC package. For example, the grounding PTH can be positioned in an example core (e.g., a package core, a substrate core) of an example package substrate of the IC package, such that the grounding PTH surrounds (e.g., encircles, fully encircles, extends continuously around, etc.) one or more example signal vias (and/or portion(s) thereof) positioned in the substrate. In some examples, dielectric material is positioned in the grounding PTH, and the signal via(s) extend through the dielectric material. In some examples, one or more example grounding members (e.g., grounding micro-vias) are coupled to the grounding PTH. In some such examples, the grounding members extend through example dielectric layers of the package substrate to electrically couple the grounding PTH to a ground plane of the package substrate. In some examples, one or more electrical signals can travel through the signal via(s) between two or more locations of the package substrate. By providing the grounding PTH around the signal via(s), examples disclosed herein can shield the electrical signals from the effects of crosstalk from other signals through the package substrate, thereby improving the quality and/or reliability of the electrical signals. Further, by reducing the effects of crosstalk between neighboring signals in a package substrate, examples disclosed herein enable signal vias to be positioned closer together (e.g., at a reduced pitch) in the package substrate (e.g., compared to when the grounding PTHs disclosed herein are not used). As a result, examples disclosed herein can increase a number of the signal vias included in the package substrate, thus increasing a signaling bandwidth of the package substrate.

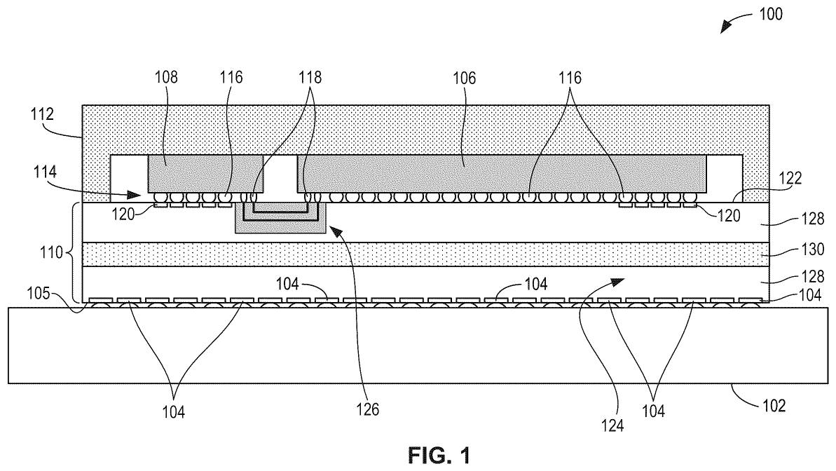

FIG. 1 illustrates an example integrated circuit (IC) package 100 constructed in accordance with teachings disclosed herein. In the illustrated example, the IC package 100 is electrically coupled to a circuit board 102 via an array of contact pads or lands 104 on a mounting surface 105 (e.g., a bottom surface) of the package 100. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, the second level interconnects are used to electrically couple the IC package 100 to some component other than a circuit board (e.g., an interposer, another IC package, etc.). In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. In some examples, the substrate 110 includes interconnects (e.g., internal interconnects) including metal traces and vias that are not shown in FIG. 1 in the interest of clarity. The contact pads 120 on the inner surface 122 of the package substrate 110 are electrically coupled to the pads 104 on the bottom (external) surface 105 of the substrate 110 (e.g., a surface opposite the inner surface 122) via the internal interconnects within the substrate 110. As a result, there is a continuous electrical signal path (e.g., a continuous electrical signal path) between the interconnects 114 of the dies 106, 108 and the pads 104 mounted to the circuit board 102 that pass through the contact pads 120 and the internal interconnects provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

In some examples, the internal interconnects of the substrate 110 are defined by traces or routing in separate conductive (e.g., metal) layers within buildup regions 128 on one or both sides of a substrate core 130 (e.g., a base substrate) in the package substrate 110. In such examples, the buildup regions 128 include dielectric layers to separate the different conductive layers. In such examples, the traces or routing in the different conductive layers are electrically coupled (to define the complete electrical path of the internal interconnects) by conductive (e.g., metal) vias extending between the different conductive layers. Further, in some examples, the internal interconnects include vias that extend through the substrate core 130.

In some examples, the substrate core 130 is an organic core or organic substrate including one or more organic materials (e.g., epoxy resin, polyimide, etc.). In some examples, the substrate core 130 is a glass substrate or glass core. In some examples, glass substrates (e.g., the glass core 130) includes quartz, fused silica, and/or borosilicate glass. In some examples, glass substrates (e.g., the glass core 130) includes at least 20% (by weight) of each of silicon (Si) and oxygen (O). In other examples, glass substrates (e.g., the glass core 130) includes greater amounts of at least one of silicon or oxygen (e.g., at least 25 wt %, at least 30 wt %, at least 35 wt %, at least 40 wt %, etc.). In some examples, glass substrates (e.g., the glass core 130) includes at least 5% (by weight) of aluminum (Al). In some examples, glass substrates (e.g., the glass core 130) include at least one glass layer and do not include epoxy and do not include glass fibers (e.g., does not include an epoxy-based prepreg layer with glass cloth). In some examples, glass substrates (e.g., the glass core 130) correspond to a single piece of glass that extends the full height/thickness of the core. In some examples, the glass core 130 has a rectangular shape that is substantially coextensive, in plan view, with the layers above and below the core (e.g., substantially coextensive with the buildup regions 128). The glass core 130 provides stiffness and mechanical support or strength for the package substrate 110 and the rest of the package 100. Thus, the glass core 130 is an example means for strengthening the package substrate 110. In some examples, the thickness of the glass core 130 is driven by the size (e.g., footprint) of the package 100. For example, in some instances, larger packages 100 include a substrate 110 with a larger (e.g., thicker) core 130 as compared with smaller packages 100 where the core does not need to be as thick.

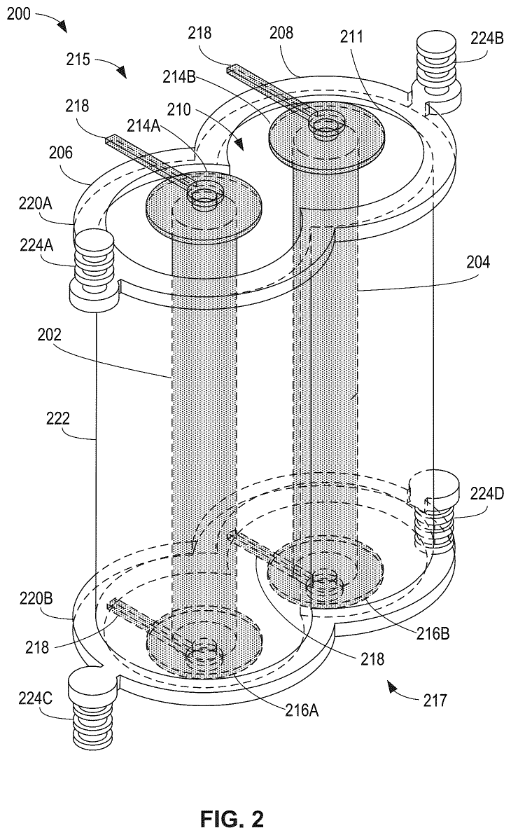

FIG. 2 illustrates an example grounding PTH (e.g., a ground via, a casing, a metal casing, a metal shield, a metal shell) 200 that may be implemented in the example IC package 100 of FIG. 1. For example, the grounding PTH 200 may be implemented in the package substrate 110. More particularly, in some examples, the grounding PTH 200 extends through the core 130 of the package substrate 110. In other examples, the grounding PTH 200 may be implemented in the first die 106, the second die 108, and/or the interconnect bridge 126 of FIG. 1. In the illustrated example of FIG. 2, first and second example vias (e.g., signal vias, signal PTHs, conductive vias) 202, 204 are positioned in the grounding PTH 200, such that the grounding PTH 200 surrounds at least a portion of the vias 202, 204. In some examples, the grounding PTH 200 is defined by a metal wall extending continuously around the vias 202, 204 and/or fully encircling the vias 202, 204. In some examples, the signal vias 202, 204 correspond to a differential pair of signal vias that may be used to transmit information (e.g., signals) between two or more locations of the IC package 100. While two of the vias 202, 204 are positioned in the grounding PTH 200 of FIG. 2, a different number of the vias 202, 204 may be used instead. For example, one of the vias 202, 204 may be omitted, and a remaining one of the vias 202, 204 may serve as a single-ended signal via.

In the illustrated example of FIG. 2, a cross-section of the grounding PTH 200 is peanut-shaped. For example, a cross-section of the grounding PTH 200 includes a first example circular portion (e.g., a first rounded portion) 206 overlapping with and/or coupled to a second example circular portion (e.g., a second rounded portion) 208. In this example, the first via 202 is positioned at or near a center of the first circular portion 206 (e.g., the first via 202 and the first circular portion 206 are substantially concentric and/or coaxially aligned), and the second via 204 is positioned at or near a center of the second circular portion 208 (e.g., the second via 204 and the second circular portion 208 are substantially concentric and/or coaxially aligned). In some examples, a cross-sectional shape of the grounding PTH 200 may be different (e.g., circular, elliptical, etc.), and/or positions of the vias 202, 204 within the grounding PTH may be different (e.g., offset from the center(s) of the first circular portion 206 and/or the second circular portion 208). In some examples, a distance (e.g., a spacing) between a first center of the first via 202 and a second center of the second via 204 is 400 micrometers or less. In some examples, the distance between the first center of the first via 202 and the second center of the second via 204 may be different (e.g., greater than 400 micrometers).

In this example, the vias 202, 204 include an example conductive material (e.g., metal) that enables transmission of electrical signals therethrough. For example, the conductive material can include copper, silver, and/or a different metallic material. In some examples, the vias 202, 204 can be solid metal extending from an outer surface (e.g., an outer diameter) all the way to the center of the vias 202, 204. In some examples, the grounding PTH 200 includes conductive material that is substantially the same as the conductive material used for the vias 202, 204. Further, a first example dielectric material 210 is positioned in the grounding PTH 200 between the vias 202, 204 and an inner surface 211 of the grounding PTH 200. In some examples, a second example dielectric material (e.g., a non-conductive polymer) is positioned in the vias 202, 204 (e.g., the vias 202, 204 are defined by metal walls with the second dielectric material disposed within an interior of the metal walls). In such examples, the second dielectric material can be the same as or different from the first dielectric material 210. In this example, first example contact pads 214A, 214B are coupled to respective ones of the vias 202, 204 at a first end (e.g., a front end) 215 of the vias 202, 204, and second example contact pads 216A, 216B are coupled to the respective ones of the vias 202, 204 at a second end (e.g., a back end) 217 of the vias 202, 204. In some examples, example traces 218 are coupled to the first and second contact pads 214A, 214B, 216A, 216B and, thus, are electrically coupled to corresponding ones of the vias 202, 204. In some examples, the traces 218 can be used to transmit electrical signals and/or power to and/or from the corresponding vias 202, 204.

In the illustrated example of FIG. 2, the grounding PTH 200 includes first and second example grounding pads 220A, 220B at the respective front and back ends 215, 217 of the grounding PTH 200. In this example, the grounding pads 220A, 220B correspond to flanged portions coupled to and/or extending from example sidewalls 222 of the grounding PTH 200. In some examples, a thickness of the sidewalls 222 (e.g., measured in a direction perpendicular to an axial length of the grounding PTH 200) is less than a thickness of the grounding pads 220A, 220B (e.g., measured in a direction parallel to an axial length of the grounding PTH 200). In some examples, the thickness of the sidewalls 222 can be the same as or greater than the thickness of the grounding pads 220A, 220B. In the example of FIG. 2, example grounding members (e.g., grounding micro-vias) 224A, 224B, 224C, 224D are coupled to corresponding ones of the grounding pads 220A, 220B. In some examples, two of the grounding members 224A, 224B are coupled to opposite ends (e.g., distal ends) of the first grounding pad 220A, and two of the grounding members 224C, 224D are coupled to opposite ends (e.g., distal ends) of the second grounding pad 220B. In other examples, less than two (e.g., one) or more than two grounding members 224A, 224B, 224C, 224D may be coupled to respective ones of the grounding pads 220A, 220B. In some examples, a number of the grounding members 224A, 224B, 224C, 224D and/or locations thereof may be different.

In some examples, flow of electrical signals through one or more example vias (e.g., the vias 202, 204 of FIG. 2) may result in crosstalk between different signal paths of the IC package 100. In the illustrated example of FIG. 2, the grounding PTH 200 can be used to reduce crosstalk in the IC package 100 by shielding the vias 202, 204 from electrical signals passing through one or more other vias in the IC package 100. For example, the grounding PTH 200 can provide a return path for electrical signals to an example ground (e.g., a ground plane) of the IC package 100. In some examples, the grounding members 224A, 22B, 224C, 224D electrically couple the grounding PTH 200 to the ground, such that electrical current can travel from the grounding PTH 200 to the ground though the grounding members 224A, 22B, 224C, 224D. In some examples, by reducing the effects of crosstalk, the grounding PTH 200 can improve electrical performance of the vias 202, 204 and, thus, the IC package 100 of FIG. 1.

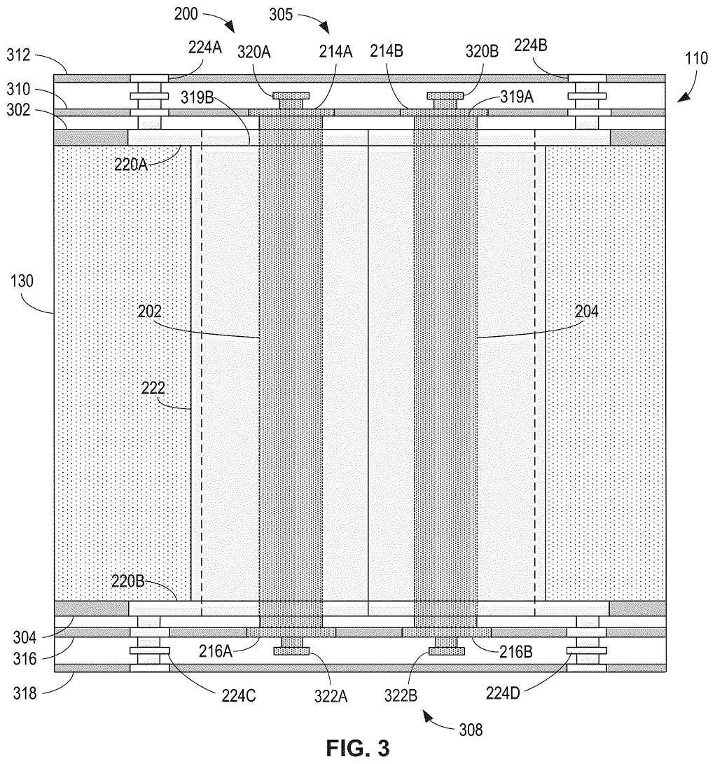

FIG. 3 is a side view of the example grounding PTH 200 of FIG. 2. In the illustrated example of FIG. 3, the sidewalls 222 of the grounding PTH 200 extend between a first example front-end metal layer (e.g., a 1F layer) 302 and a first example back-end metal layer (e.g., a 1B layer) 304 of an example substrate (e.g., the package substrate 110 of FIG. 1). For example, the first front-end metal layer 302 is proximate a front end 305 of the substrate, and the first back-end metal layer 304 is proximate a back end 308 of the substrate. In some examples, the first front-end metal layer 302 and the first back-end metal layer 304 are adjacent opposing sides of the core 130 of the package substrate 110. Thus, in some examples, the length (e.g., height) of the sidewalls 222 of the grounding PTH 200 corresponds to a thickness of the core 130. In some examples, the thickness of the core 130 is 1 millimeter or less, is at least 750 microns and up to 1000 microns, etc. In this example, the substrate further includes a second example front-end metal layer (e.g., a 2F layer) 310 and a third example front-end metal layer (e.g., a 4F layer) 312 proximate the front end 305. In this example, the second front-end metal layer 310 is spaced apart from the first front-end metal layer 302 and closer to the front end 305 compared to the first front-end metal layer 302. Similarly, the third front-end metal layer 312 is spaced apart from the second front-end metal layer 310 and is closer to the front end 305 compared to the first and second front-end metal layers 302, 310. Additionally, the substrate includes a second example back-end metal layer (e.g., a 2B layer) 316 and a third example back-end metal layer (e.g., a 4B layer) 318 proximate the back end 308. In this example, the second back-end metal layer 316 is spaced apart from the first back-end metal layer 304 and is closer to the back end 308 compared to the first back-end metal layer 304. Similarly, the third back-end metal layer 318 is spaced apart from the second back-end metal layer 316 and is closer to the back end 308 compared to the first and second back-end metal layers 304, 316. In this example, the vias 202, 204 extend between the second front-end metal layer 310 and the second back-end metal layer 316, and the grounding PTH 200 extends between the first front-end metal layer 302 and the first back-end metal layer 304. As a result, a first example end 319A of the vias 202, 204 are further away from a surface of the core 130 compared to a second end 319B of the grounding PTH 200.

In the illustrated example of FIG. 3, the first and second front-end metal layers 302, 312 and the first and second back-end metal layers 304, 316 correspond to routing layers of the package substrate 110 along which example traces can be positioned, where different ones of the traces can be used for signaling and/or for supplying power to one or more locations along a respective one of the metal layers 302, 304, 312, 316. Further, the third front-end metal layer 312 and the third back-end metal layer 318 correspond to ground layers (e.g., ground planes) of the package substrate 110. In the example of FIG. 3, the metal layers 302, 304, 310, 312, 316, 318 include a conductive material (e.g., copper, silver, etc.). In some examples, the package substrate 110 further includes an example dielectric material positioned between ones of the metal layers 302, 304, 310, 312, 316, 318 (e.g., between the first and second front-end metal layers 302, 310, between the second and third front-end metal layers 310, 312, between the first and second back-end metal layers 304, 316, and/or between the second and third back-end metal layers 316, 318). In some examples, the dielectric material between the ones of the metal layers 302, 304, 310, 312, 316, 318 can be the same as or different from the first dielectric material 210 in the grounding PTH 200 of FIG. 1. While three of the front-end metal layers 302, 310, 312 and three of the back-end metal layers 304, 316, 318 are shown in FIG. 3, a different number (e.g., more than three, less than three) of the front-end metal layers 302, 310, 312 and/or the back-end metal layers 304, 316, 318 may be used instead.

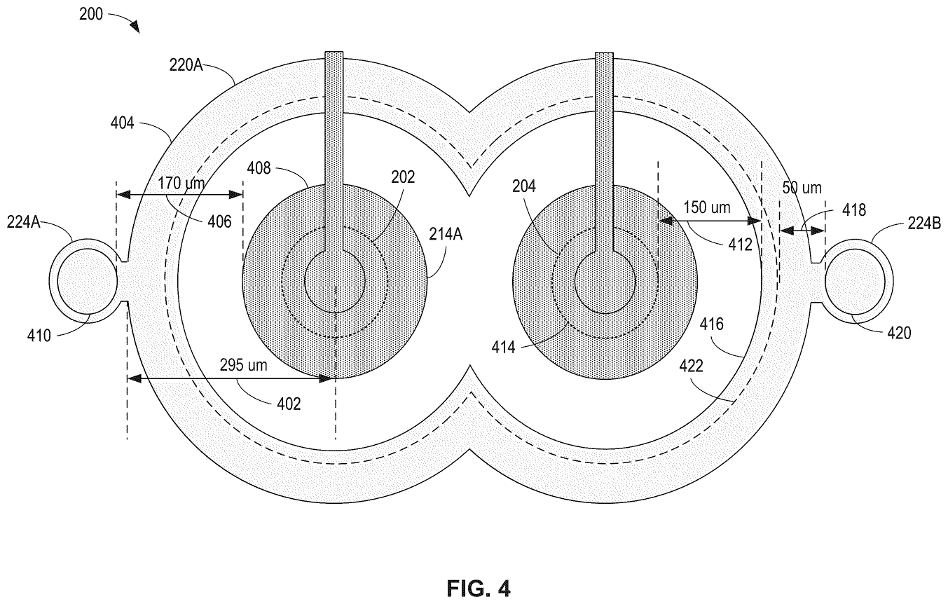

In the illustrated example of FIG. 3, the first grounding pad 220A of the grounding PTH 200 is positioned in and/or is substantially flush with the first front-end metal layer 302, and the second grounding pad 220B of the grounding PTH 200 is positioned in and/or is substantially flush with the first back-end metal layer 304. Further, the vias 202, 204 extend between the respective first contact pads 214A, 214B positioned at the second front-end metal layer 310 and the respective second contact pads 216A, 216B positioned at the second back-end metal layer 316. In some examples, the traces 218 of FIG. 2 extend from first and second example via pads 320A, 320B, 322A, 322B coupled to respective ones of the first and second contact pads 214A, 214B, 216A, 216B. In some examples, the first via pads 320A, 320B are in an example 3F layer (e.g., a fourth example front-end metal layer) positioned between the second and third front-end metal layers 310, 312, and the second via pads 322A, 322B are in an example 3B layer (e.g., a fourth example back-end metal layer) positioned between the second and third back-end metal layers 316, 318. In such examples, the traces 218 extend along the respective ones of the 3F layer and/or the 3B layer. In the example of FIG. 3, first ones of the grounding members 224A, 224B extend from the first grounding pad 220A at the first front-end metal layer 302 to the third front-end metal layer 312, and second ones of the grounding members 224C, 224D extend from the second grounding pad 220B at the first back-end metal layer 304 to the third back-end metal layer 318. As such, the grounding members 224A, 224B, 224C, 224D provide a return path from the grounding PTH 200 to the respective one(s) of the third front-end metal layer 312 and/or the third back-end metal layer 318. In some examples, one(s) of the grounding members 224A, 224B, 224C, 224D, the grounding PTH 200, and/or the vias 202, 204 can extend between different ones of the metal layers 302, 304, 310, 312, 316, 318 than those shown in FIG. 4. For instance, in some examples, the first and second contact pads 214A, 214B of the vias 202, 204 may be located in the same metal layer (e.g., the first front-end and back-end metal layers 302, 304) as the first and second grounding pads 220A, 220B.

FIG. 4 is a top view of the example grounding PTH 200 of FIGS. 2 and/or 3. In the illustrated example of FIG. 4, example dimensions of the grounding PTH 200 and/or the vias 202, 204 are shown. For example, a first example distance 402 between a center of the first via 202 and an outer edge 404 of the first grounding pad 220A is approximately 295 micrometers. Further, a second example distance 406 between an outer edge 408 of the first contact pad 214A and a surface 410 of the first grounding member 224A is approximately 170 micrometers. A third example distance 412 between an outer surface 414 of the second via 204 and a first inner edge 416 of the grounding PTH 200 is approximately 150 micrometers. In this example, a fourth example distance 418 between a surface 420 of the second grounding member 224B and a second inner edge 422 of the grounding PTH 200 is approximately 50 micrometers. In some examples, at least one of the first distance 402, the second distance 406, the third distance 412, or the fourth distance 418 may be different.

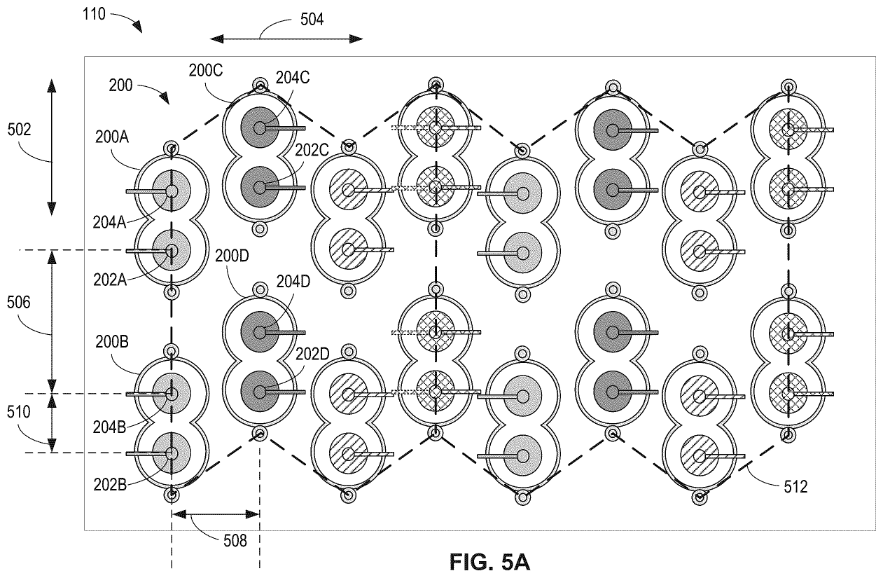

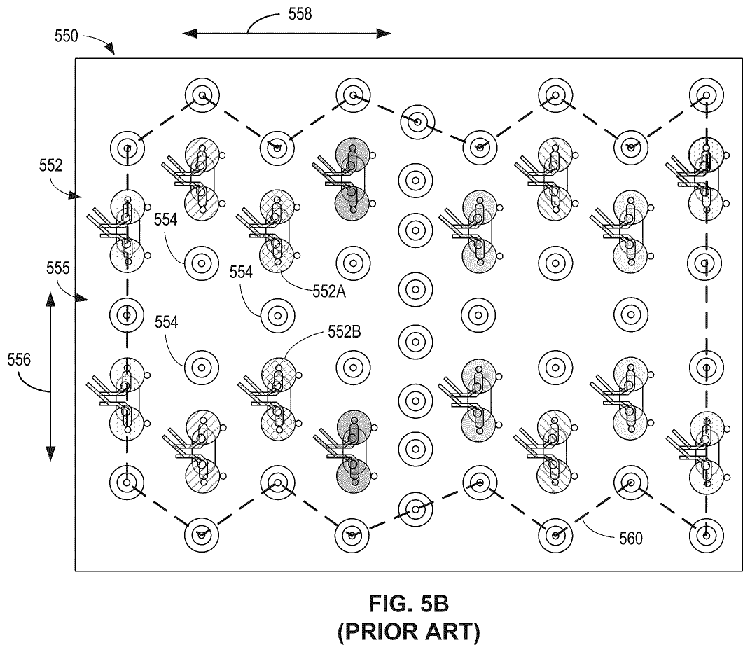

FIG. 5A is a top view of the example package substrate 110 of the example IC package 100 of FIG. 1. In the illustrated example of FIG. 5A, multiple ones of the example grounding PTH 200 and multiple corresponding pairs of the vias 202, 204 of FIGS. 2-4 are positioned in the package substrate 110. For example, the package substrate 110 includes an example array of grounding PTHs 200 including a first pair of example vias 202A, 204A positioned in a first example grounding PTH 200A, a second pair of example vias 202B, 204B positioned in a second example grounding PTH 200B, a third pair of example vias 202C, 204C positioned in a third example grounding PTH 200C, a fourth pair of example vias 202D, 204D positioned in a fourth example grounding PTH 200D, etc. In the illustrated example of FIG. 5A, adjacent ones of the grounding PTHs 200 (e.g., the first and second grounding PTHs 200A, 200B, the third and fourth grounding PTHs 200C, 200D, etc.) are substantially aligned along a first example direction 502, and adjacent ones of the grounding PTHs 200 (e.g., the first and third grounding PTHs 200A, 200C, the second and fourth grounding PTHs 200B, 200D, etc.) are offset from one another along a second example direction 504 perpendicular to the first direction 502. In some examples, the offset corresponds to a spacing or pitch between the vias 202, 204 within a corresponding PTH 200. In some examples, the offset is such that ones of the vias 202, 204 are aligned in the second direction 504 (e.g., such that the second via 204A of the first grounding PTH 200A is substantially aligned with the first via 202C of the third grounding PTH 200C in the second direction 504). In some examples, positions and/or orientations of one(s) of the grounding PTHs 200 may be different.

In some known package substrates, rather than implementing the example grounding PTHs 200 that surround or encompass pairs of vias 202, 204, one or more grounding vias may be positioned in the package substrate 110 between adjacent pairs of the vias 202, 204 to prevent and/or reduce crosstalk therebetween (as shown in FIG. 5B and discussed further below). In contrast with such known approaches, by providing the grounding PTHs 200 around corresponding pairs of the vias 202, 204, as shown in FIG. 5A, a number of the grounding vias to be positioned in the package substrate 110 may be reduced. For example, the package substrate 110 of FIG. 5A does not include separate grounding vias between adjacent pairs of the vias 202, 204. As a result, adjacent pairs of the vias 202, 204 may be positioned closer together, such that a surface area of the package substrate 110 necessitated to implement the vias 202, 204 may be reduced (e.g., compared to when separate grounding vias are used). In this example, a first example distance 506 between centers of adjacent ones of the vias 202, 204 in adjacent ones of the grounding PTHs 200 along the first direction 502 (e.g., between a center of the first via 202A of the first grounding PTH 200A and a center of the second via 204B of the second grounding PTH 200B) is approximately 940 micrometers. Further, a second example distance 508 between centers of adjacent ones of the vias 202, 204 in adjacent ones of the grounding PTHs 200 along the second direction 504 is approximately 600 micrometers. In some examples, a third example distance 510 between the centers of the vias 202, 204 in a corresponding one of the grounding PTHs 200 is approximately 383 micrometers. In some examples, at least one of the first distance 506, the second distance 508, or the third distance 510 may be different. In the illustrated example of FIG. 5A, sixteen pairs of the vias 202, 204 are included in a first example area 512 of the package substrate 110, where the first area 512 is represented by a dashed line in FIG. 5A. In this example, the first area 512 is approximately 9.4 square millimeters. In some examples, a size of the first area 512 may be different.

FIG. 5B is a top view of a known package substrate 550 not including the grounding PTHs 200 of FIG. 5A. In FIG. 5B, instead of using the grounding PTHs 200 to electrically shield electrical signals from crosstalk between neighboring pairs of signal vias 552 (e.g., a first pair of signal vias 552A and a second pair of signal vias 552B), the known package substrate 550 of FIG. 5B implements one or more ground vias 554 between the neighboring pairs of signal vias 552. For instance, a row 555 of the ground vias 554 are implemented along the second direction 558 between the first pair of signal vias 552A and the second pair of signal vias 552B. As a result, distances between the neighboring pairs of vias 552 in the known package substrate 550 of FIG. 5B may be greater compared to the distances between adjacent pairs of the vias 202, 204 of the package substrate 110 of FIG. 5A (e.g., greater than 940 micrometers along a first direction 556, greater than 600 micrometers along a second direction 558, etc.). Accordingly, a greater number of signal vias may be implemented in the package substrate 110 of FIG. 5A compared to the known package substrate 550 of FIG. 5B. In FIG. 5B, sixteen pairs of the signal vias 552 are implemented in a second area 560 (e.g., as defined by the dashed line in FIG. 5B), where the second area 560 is approximately 15.2 square millimeters (e.g., greater than a size of the first area 512 of FIG. 5A).

While the grounding PTHs 200 and the vias 202, 204 are described as being implemented in the package substrate 110 in the illustrated examples of FIGS. 2, 3, 4, and/or 5A, one or more of the grounding PTHs 200 and/or the vias 202, 204 may additionally or alternatively be implemented in one or more different locations of the IC package 100 of FIG. 1. For example, one or more of the grounding PTHs 200 and/or the corresponding vias 202, 204 may be implemented in the first die 106, the second die 108, and/or the interconnect bridge 126 of FIG. 1.

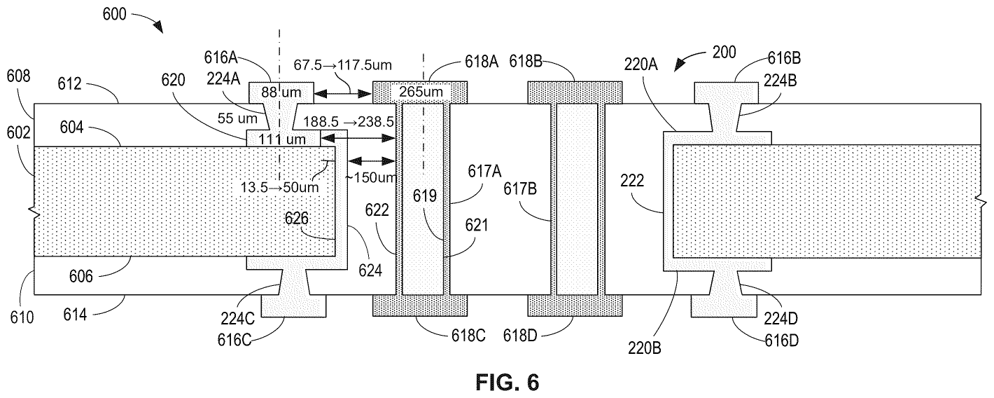

FIG. 6 is a cross-sectional view of an example package substrate 600 implementing the example grounding PTH 200 and the example vias 202, 204 of FIGS. 2, 3, 4, and/or 5A. In the illustrated example of FIG. 6, the package substrate 600 includes an example core 602 including a first example core surface 604 and a second example core surface 606 (e.g., opposite the first core surface 604). Further, first and second example dielectric layers 608, 610 are positioned (e.g., fabricated, provided) on respective ones of the first and second core surfaces 604, 606, where the first dielectric layer 608 defines a first example dielectric surface 612 and the second dielectric layer 610 defines a second example dielectric surface 614. In some examples, the core 602 includes at least one of glass and/or an organic material, and the dielectric layers 608, 610 include dielectric material.

In the illustrated example of FIG. 6, the example grounding PTH 200 is positioned in the package substrate 600 such that the example sidewalls 222 extend between the first and second core surfaces 604, 606 of the core 602. Further, the first grounding pad 220A is positioned on the first core surface 604, and the second grounding pad 220B is positioned on the second core surface 606. In this example, the first and second grounding members 224A, 224B are positioned in the first dielectric layer 608 and extend between the first core surface 604 and the first layer surface 612. Further, the third and fourth grounding members 224C, 224D are positioned in the second dielectric layer 610 and extend between the second core surface 606 and the second layer surface 614. In this example, the first and second grounding members 224A, 224B are coupled to respective first and second example pads 616A, 616B positioned on the first layer surface 612, and the third and fourth grounding members 224C, 224D are coupled to respective third and fourth example pads 616C, 616D positioned on the second layer surface 614. In the illustrated example of FIG. 6, first and second example vias 617A, 617B are positioned in the grounding PTH 200 and extend between the first and second layer surfaces 612, 614. In this example, unlike the solid vias 202, 204 of FIGS. 2-4, the vias 617A, 617B of FIG. 6 include metal sidewalls 619 and an example dielectric material 621 positioned in the metal sidewalls 619. In this example, the first and second vias 617A, 617B are coupled to respective first and second example contact pads 618A, 618B positioned on the first layer surface 612, and the first and second vias 617A, 617B are further coupled to respective third and fourth example contact pads 618C, 618D positioned on the second layer surface 614.

In the illustrated example of FIG. 6, example dimensions associated with the first grounding member 224A are shown. In some examples, similar example dimensions can be used for one(s) of the second, third, and fourth grounding members 224B, 224C, 224D. In the example of FIG. 6, a first example distance between the first pad 616A and the first contact pad 618A is at least 67.5 micrometers and up to 117.5 micrometers. In some examples, a first diameter of the first pad 616A is approximately 88 micrometers, and a second diameter of the first contact pad 618A is approximately 265 micrometers. In this example, the first grounding member 224A includes an example base portion 620, and a third example diameter of the base portion 620 is approximately 111 micrometers. In some examples, a fourth example diameter of a via (e.g., a portion of the first grounding member 224A) between the base portion 620 and the first pad 616A is approximately 55 micrometers. In the illustrated example of FIG. 6, a second example distance between a first outer surface 622 of the first via 617A and a first inner surface 624 of the grounding PTH 200 is approximately 150 micrometers, and a third example distance between the first outer surface 622 of the first via 617A and the base portion 620 of the first grounding member 224A is at least 188.5 micrometers and up to 238.5 micrometers. In this example, a fourth example distance between the base portion 620 of the first grounding member 224A and a second outer surface 626 of the grounding PTH 200 is at least 13.5 micrometers and up to 50 micrometers. In some examples, at least one of the dimensions (e.g., the first diameter, the second diameter, the third diameter, the fourth diameter of the first grounding member 224A, the first distance, the second distance, the third distance, and/or the fourth distance) can be different.

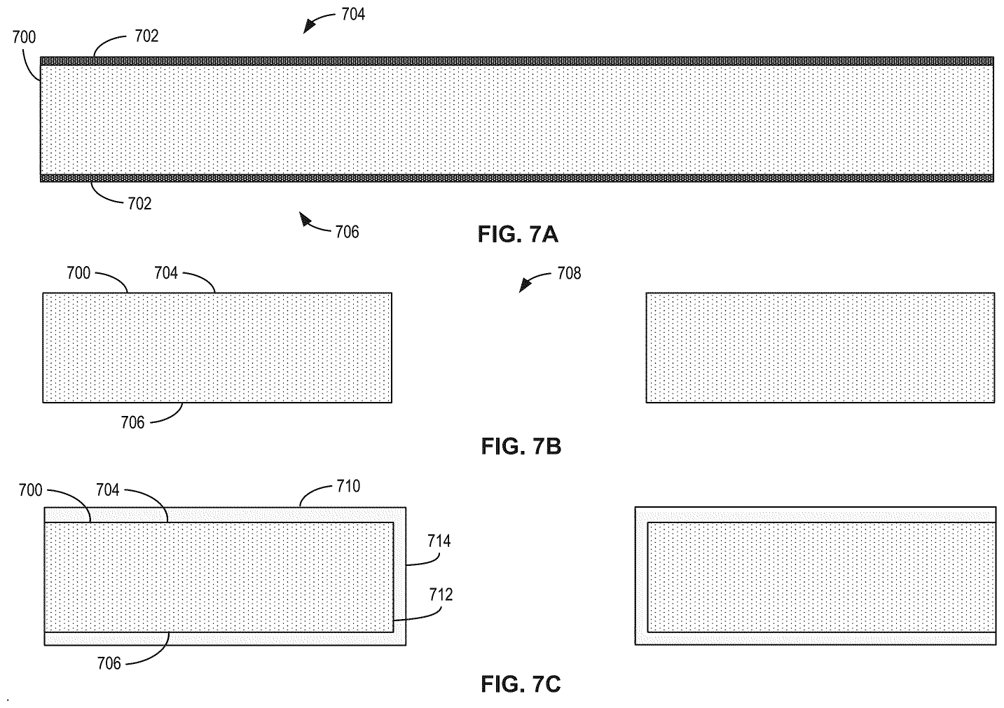

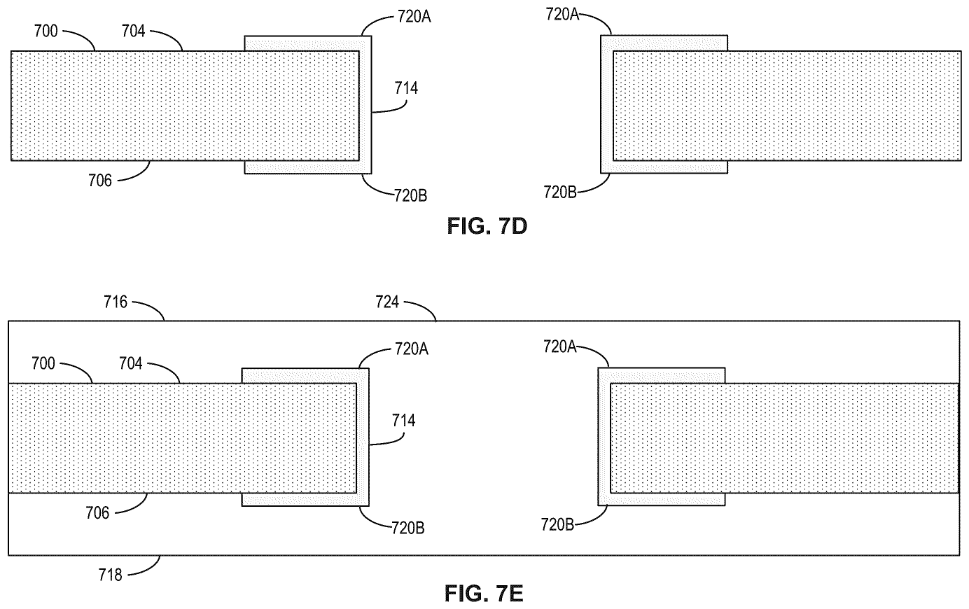

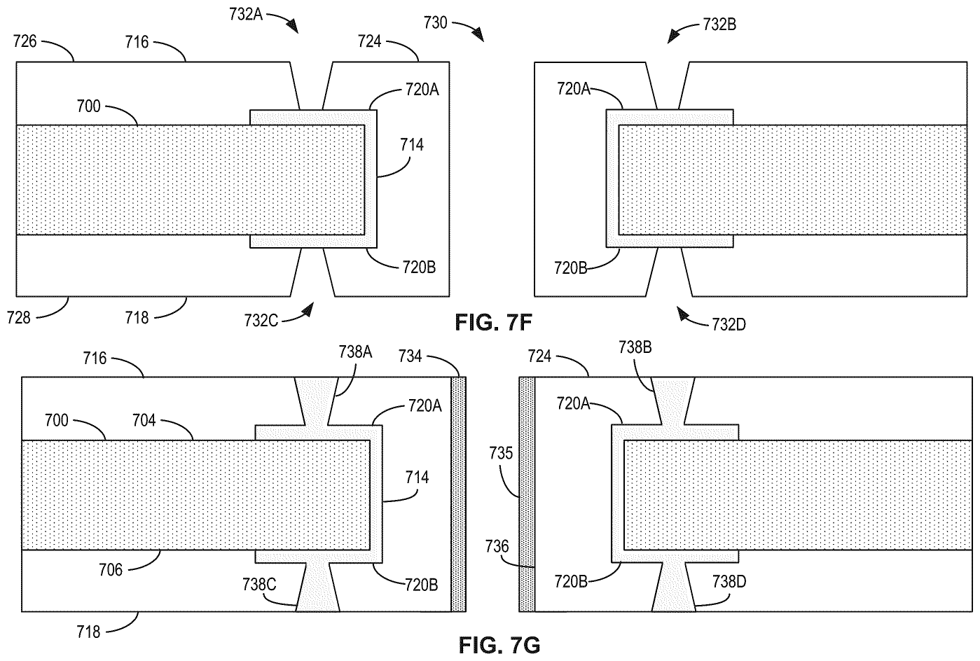

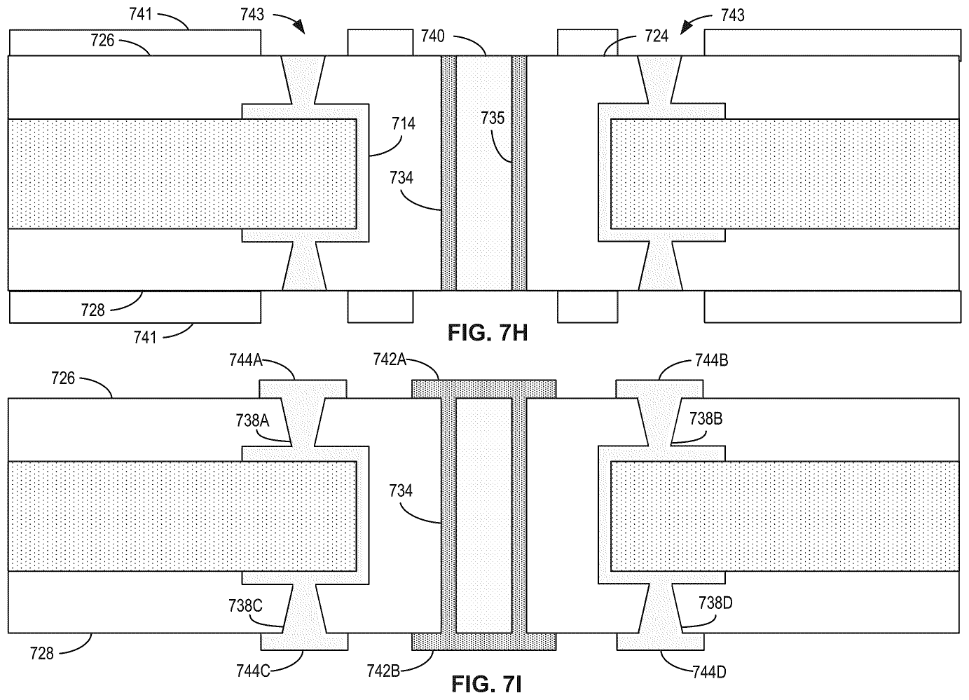

An example process to produce an example package substrate (e.g., the package substrate 110 of FIG. 1 and/or the example package substrate 600 of FIG. 6) including an example grounding PTH (e.g., the grounding PTH 200 of FIGS. 2, 3, 4, 5A, and/or 6) is described below in connection with FIGS. 7A, 7B, 7C, 7D, 7E, and/or 7F. In particular, FIG. 7A is a cross-sectional view of an example core (e.g., a substrate core) 700 that may be implemented in the example IC package 100 of FIG. 1. For example, the core 700 of FIG. 7A may be implemented in the package substrate 110 of FIG. 1, the package substrate 600 of FIG. 6, the first die 106 of FIG. 1, the second die 108 of FIG. 1, and/or the interconnect bridge 126 of FIG. 1. In some examples, the core 700 can include glass and/or an example organic material. In the illustrated example of FIG. 7A, the core 700 is fabricated with example foil (e.g., metal foil, copper foil) 702 positioned on first and second example core surfaces 704, 706 of the core 700. In some examples, the foil 702 is used to protect the first and second core surfaces 704, 706 from damage during transportation of the core 700. In some examples, the foil 702 can be removed and/or a thickness of the foil 702 can be reduced (e.g., by etching). In some examples, the core 700 can be fabricated with the foil 702 on either the first core surface 704 or the second core surface 706, or the core 700 can be fabricated without the foil 702.

FIG. 7B illustrates the example core 700 of FIG. 7A with the foil 702 removed and/or reduced. In the illustrated example of FIG. 7B, an example cavity (e.g., a first through-hole) 708 is provided in the core 700, where the cavity 708 extends through the core 700 between the first and second core surfaces 704, 706 of the core 700. In some examples, the cavity 708 is produced by drilling and/or otherwise providing at least one through-hole in the core 700. For example, the cavity 708 can be a circular cavity in which one through-hole is provided in the core 700. In some examples, a first through-hole (e.g., a first circular cavity) can be provided in the core 700, and a second through-hole (e.g., a second circular cavity) can be provided in the core 700 and overlapping with the first through-hole to produce the cavity 708 having a peanut-shaped cross-section (e.g., as shown in FIGS. 2 and/or 4).

FIG. 7C illustrates the example core 700 of FIGS. 7A and/or 7B with a first example metal layer (e.g., a first metallic plating) 710 provided on one or more surfaces of the core 700. For example, the metal layer 710 can be provided on at least one of the first core surface 704, the second core surface 706, or example sidewalls 712 of the cavity 708. In some examples, the metal layer 710 is provided using at least one of an eless plating method or an elytic plating method. In some examples, the metal layer 710 is provided on the sidewalls 712 of the cavity 708 to produce a portion of an example grounding PTH (e.g., a casing, a metal casing) 714 in the cavity 708. In some examples, the metal layer 710 includes at least one of copper or silver.

FIG. 7D illustrates the example core 700 of FIGS. 7A, 7B, and/or 7C with portions of the first metal layer 710 removed. For example, the portions of the first metal layer 710 can be removed after a patterning process to expose portions of the first and second core surfaces 704, 706. In some examples, the portions of the first metal layer 710 are removed (e.g., via an etching process) to define first and second grounding pads 720A, 720B of the grounding PTH 714, where the first grounding pad 720A is positioned on the first core surface 704 and the second grounding pad 720B is positioned on the second core surface 706.

FIG. 7E illustrates the example core 700 of FIGS. 7A, 7B, 7C, and/or 7D including first and second example dielectric layers 716, 718 on the first and second example core surfaces 704, 706 of the core 700, respectively. The example dielectric layers 716, 178 correspond to the first dielectric layers in buildup regions (e.g., the buildup regions 128 of FIG. 1) on either side of the core 700. In the illustrated example of FIG. 7C, the first and second dielectric layers 716 are provided and/or fabricated on the respective first and second core surfaces 704, 706 of the core 700 by providing an example dielectric material 724 on the first and second core surfaces 704, 706. Additionally, in the illustrated example of FIG. 7E, the dielectric material 724 is provided in the grounding PTH 714 (e.g., using a lamination technique, filling with a mold compound, etc.) to fill the grounding PTH 714. In some examples, the dielectric material 724 is provided in the grounding PTH 714 prior to fabrication of the dielectric layers 716, 718.

FIG. 7F illustrates the example core 700 of FIGS. 7A, 7B, 7C, 7D, and/or 7E including one or more example openings (e.g., holes, through-holes) in the example dielectric material 724. For example, a second example through-hole 730 is provided in the dielectric material 724 positioned in the grounding PTH 714. In this example, the second through-hole 730 extends between first and second layer surfaces (e.g., dielectric layer surfaces, build-up layer surfaces) 726, 728 of the dielectric layers 716, 718. Stated differently, the second plated through-hole extends along an inside of a first plated through-hole (e.g., the grounding PTH 714). In this example, the second through-hole 730 is substantially coaxial (e.g., coaxially aligned) with the grounding PTH 714. In some examples, a position of the second through-hole 730 may be different. While one second through-hole 730 is provided in the dielectric material 724 of the grounding PTH 714 in the example of FIG. 7D, a different number (e.g., two or more) through-holes may be provided in the dielectric material 724 in some examples.

In the illustrated example of FIG. 7F, example openings 732A, 732B, 732C, 732D are provided in respective ones of the dielectric layers 716, 718 to define example micro-vias therein. For example, the first and second openings 732A, 732B extend through the first dielectric layer 716 between the first layer surface 726 and the first grounding pad 720A, and the third and fourth openings 732C, 732D extend through the second dielectric layer 718 between the second layer surface 728 and the second grounding pad 720B. In some examples, the openings 732A, 732B, 732C, 732D are produced by drilling into the respective dielectric layers 716, 718. In this example, the openings 732A, 732B, 732C, 732D are tapered, such that a diameter of the openings 732A, 732B, 732C, 732D decreases from the respective layer surfaces 726, 728 to the respective grounding pads 720A, 720B. In some examples, the openings 732A, 732B, 732C, 732D can have a different shape. For example, the openings 732A, 732B, 732C, 732D can be cylindrical (e.g., the diameter of the openings 732A, 732B, 732C, 732D is substantially the same along an axial length between the respective layer surfaces 726, 728 and the respective grounding pads 720A, 720B). In this example, the second through-hole 730 and the openings 732A, 732B, 732C, 732D have a circular cross-sectional shape. In some examples, the cross-sectional shape of the second through-hole 730 and/or one or more of the openings 732A, 732B, 732C, 732D may be different.

FIG. 7G illustrates an example signal plated through-hole (PTH) (e.g., a signal via) 734 provided in the example dielectric material 724 in the example grounding PTH 714 of FIGS. 7C, 7D, 7E, and/or 7F. In this example, a longitudinal axis of the signal PTH 734 is substantially parallel to and/or extends in a same direction as a longitudinal axis of the grounding PTH 714. In the illustrated example of FIG. 7G, to produce the signal PTH 734, a second example metal layer 735 is provided in the second example through-hole 730 of FIG. 7F to coat an inner surface (e.g., sidewalls) 736 of the second through-hole 730. In some examples, the second metal layer 735 is provided in the second through-hole 730 using an eless plating technique and/or elytic plating technique. In some examples, the second metal layer 735 can include at least one of copper or silver. In the illustrated example of FIG. 7G, an example metal material is provided in one(s) of the openings 732A, 732B, 732C, 732D of FIG. 7F to produce example grounding members (e.g., grounding micro-vias) 738A, 738B, 738C, 738D in the respective dielectric layers 716, 718. For example, the first and second grounding members 738A, 738B are provided in the first dielectric layer 716 and electrically coupled to the first grounding pad 720A, and the third and fourth grounding members 738C, 738D are provided in the second dielectric layer 718 and electrically coupled to the second grounding pad 720B. In some examples, the metal material used to produce the grounding members 738A, 738B, 738C, 738D corresponds to the second metal layer 735.

In some such examples, the grounding members 738A, 738B, 738C, 738D and the signal PTH 734 can be produced in the same process (e.g., an eless plating process and/or an elytic plating process). In some examples, as a result of the eless and/or elytic plating processes, excess metal material is coupled to at least one of the first layer surface 726 or the second layer surface 728. In some such examples, the excess material can be removed from the first and second layer surfaces 726, 728 (e.g., by etching, grinding, etc.). In some examples, the grounding members 738A, 738, 738C, 738D are produced separately from the signal PTH 734 (e.g., using a separate and/or different process). For example, the openings 732A, 732B, 732C, 732D can be covered (e.g., using a resist layer coupled to the first layer surface 726 and/or the second layer surface 728) during a first plating process used to produce the signal PTH 734, and the openings 732A, 732B, 732C, 732D can be uncovered (e.g., portion(s) of the resist layer can be removed) during a second plating process to produce the grounding members 738A, 738, 738C, 738D.

FIG. 7H illustrates the example signal PTH 734 of FIG. 7G including example non-conductive material 740 positioned in the signal PTH 734. For example, the non-conductive material 740 is provided in the signal PTH 734 to fill and/or plug the signal PTH 734. In some examples, the non-conductive material 740 includes an example polymer (e.g., a non-conductive polymer). In some examples, the signal PTH 734 enables transmission of signals through the second metal layer 735 and between the first and second layer surfaces 726, 728.

In some examples, excess material from the first and second layer surfaces 726, 728 can be removed (e.g., by etching, grinding, etc.). Further, in some examples, one or more example photoresist layer(s) 741 can be provided on one or more of the layer surfaces 726, 728. In some such examples, an example pattern can be provided on the photoresist layer(s) 741 using photolithography to produce openings 743 in the photoresist layer(s) 741 that expose the grounding members 738A, 738B, 738C, 738D and the signal PTH 734.

FIG. 7I illustrates example contact pads 742A, 742B coupled to the signal PTH 734 and example via pads 744A, 744B, 744C, 744D coupled to respective ones of the grounding members 738A, 738B, 738C, 738D. For example, the first contact pad 742A and the first and second via pads 744A, 744B are fabricated on the first layer surface 726, and the second contact pad 742B and the third and fourth via pads 744C, 744D are fabricated on the second layer surface 728. In some examples, the contact pads 742A, 742B and/or the via pads 744A, 744B, 744C, 744D include a conductive material (e.g., a metal such as copper and/or silver). In some examples, the contact pads 742A, 742B and/or the via pads 744A, 744B, 744C, 744D are provided through an electroplating process onto the exposed metal within the openings 743 in the photoresist layer(s) 741 shown in FIG. 7H. FIG. 7I represents the process after the subsequent removal of the photoresist layer(s) 741. In some examples, one or more additional dielectric layers and/or conductive layers (e.g., metal layers) can be fabricated on the first dielectric layer 716 and/or the second dielectric layer 718 to complete fabrication of a package substrate (e.g., the package substrate 110 and/or the package substrate 600).

In some examples, the first via 202 of FIGS. 2, 3 and/or 4, the first via 617A of FIG. 6, and/or the signal PTH 734 of FIGS. 7G, 7H, and/or 7I implement first means for transmitting a signal. In some examples, the second via 204 of FIGS. 2, 3 and/or 4 and/or the second via 617B of FIG. 6 implement second means for transmitting a signal. In some examples, the grounding PTH 200 of FIGS. 2, 3, 4, and/or 6 and/or the grounding PTH 714 of FIGS. FIGS. 7C, 7D, 7E, 7F, 7G, 7H, and/or 7I implement means for electrically shielding. In some examples, the grounding members 224A, 224B, 224C, 224D of 2, 3, 4, and/or 6 and/or the grounding members 738A, 738B, 738C, 738D of FIGS. 7G, 7H, and/or 7I implement means for grounding.

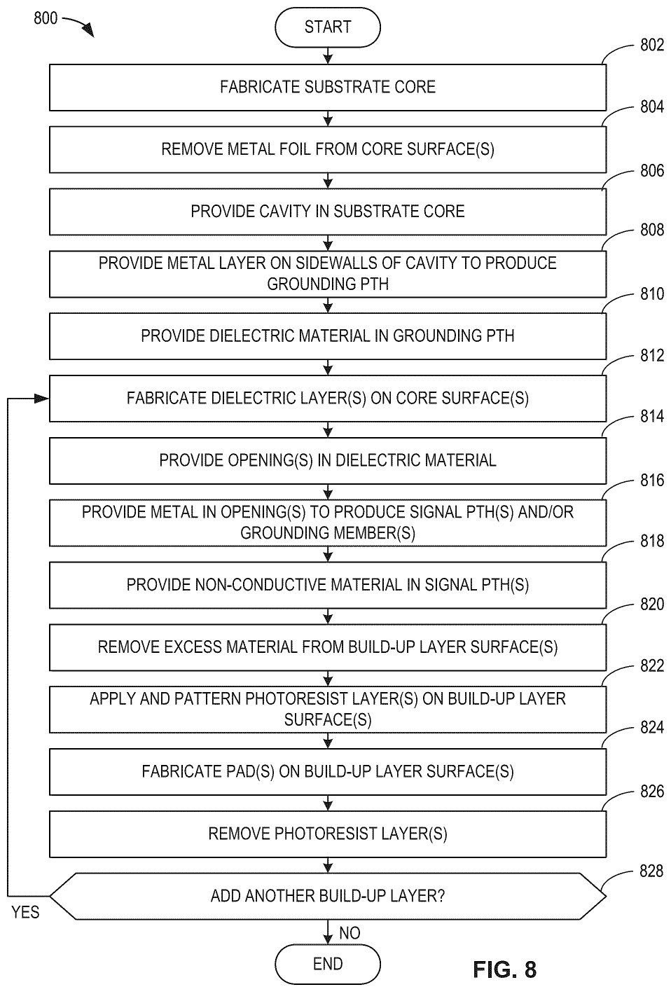

FIG. 8 is a flowchart representative of an example method 800 of manufacturing an example package substrate (e.g., the package substrate 110 of FIG. 1 and/or the package substrate 600 of FIG. 6) including an example grounding PTH (e.g., the example grounding PTH 200 of FIGS. 2, 3, 4, 5A, and/or 6 and/or the example grounding PTH 714 of FIGS. 7C, 7D, 7E, 7F, 7G, 7H, and/or 7I). In some examples, some or all of the operations outlined in the example method 800 are performed automatically by fabrication equipment that is programmed to perform the operations. Although the example method of manufacturing is described with reference to the flowchart illustrated in FIG. 8, many other methods may alternatively be used. For example, the order or execution of the blocks may be changed, and/or some of the blocks described may be combined, divided, re-arranged, omitted, eliminated, and/or implemented in any other way.

The example method 800 begins at block 802 by fabricating an example substrate core (e.g., the example core 700 of FIG. 7A). For example, the core 700 can be fabricated from at least one of glass or an organic material. In some examples, the core 700 can be fabricated with the example foil 702 of FIG. 7A positioned on the first and second core surfaces 704, 706 of the core 700.

At block 804, the example method 800 includes removing example metal foil (e.g., the foil 702 of FIG. 7A) from the first core surface 704 and/or the second core surface 706. For example, one or more portions of the foil 702 can be removed (and/or a thickness of the foil 702 can be reduced) at one or more locations of the first core surface 704 and/or the second core surface 706. In some examples, the foil 702 can be removed and/or reduced by etching.

At block 806, the example method 800 includes providing the example cavity 708 in the example core 700. For example, the cavity 708 is provided in the core 700 such that the cavity 708 extends between the first and second core surfaces 704, 706. In some examples, the cavity 708 is provided by drilling at least one through-hole in the core 700. In some examples, multiple through-holes can be provided in the core 700 to produce the cavity 708. For example, overlapping through-holes can be provided in the core 700 to produce the cavity 708 having a peanut-shaped cross-section (e.g., as shown in FIGS. 2 and/or 4).

At block 808, the example method 800 includes providing an example metal layer on the example sidewalls 712 of the cavity 708 to produce the example grounding PTH 714. For example, the example metal layer 710 of FIG. 7C can be plated and/or coated on the sidewalls 712 (e.g., using eless and/or elytic plating methods) to produce the grounding PTH 714. In some examples, portions of the metal layer 710 can be removed to define first and second grounding pads 720A, 720B of the grounding PTH 714.

At block 810, the example method 800 includes providing an example dielectric material 724 in the grounding PTH 714. For example, the dielectric material 724 can be provided in the grounding PTH 714 (e.g., using a lamination technique) such that the grounding PTH 714 is filled with the dielectric material 724.

At block 812, the example method 800 includes fabricating the example dielectric layers 716, 718 on the respective first and second example core surfaces 704, 706 of the core 700. For example, dielectric material can be provided on the first and second core surfaces 704, 706 to produce and/or fabricate the first and second dielectric layers 716, 718. In some examples, the dielectric layer(s) 716, 718 are and extension of the dielectric material added in the grounding PTH 714. Thus, in some examples, blocks 810 and 812 are part of the same fabrication process.

At block 814, the example method 800 includes providing one or more example openings (e.g., through-holes) in the dielectric material 724 (e.g., the material in the grounding PTH 714 and the material of the dielectric layer(s) 716, 718). For example, the second example through-hole 730 of FIG. 7D is provided (e.g., by drilling) in the dielectric material 724 in the grounding PTH 714 such that the second through-hole 730 extends between the first and second layer surfaces 726, 728. Additionally, the example openings 732A, 732B, 732C, 732D are provided in respective ones of the dielectric layers 716, 718 to define example micro-vias in the dielectric layers 716, 718.

At block 816, the example method 800 includes providing example metal material in in one or more of the openings (e.g., the second example through-hole 730 and/or the openings 732A, 732B, 732C, 732D) to produce the example signal PTH 734 and/or the example grounding members 738A, 738B, 738C, 738D of FIG. 7G. For example, the metal layer 735 is provided in the second through-hole 730 to coat the inner surface 736 of the second through-hole 730 (e.g., using eless and/or elytic plating techniques). Additionally or alternatively, the metal material is provided in one(s) of the openings 732A, 732B, 732C, 732D to produce the respective one(s) of the grounding members 738A, 738B, 738C, 738D.

At block 818, the example method 800 includes providing the example non-conductive material 740 of FIG. 7H in the signal PTH 734. For example, the non-conductive material 740 is provided in the signal PTH 734 to fill and/or plug the signal PTH 734.

At block 820, the example method 800 includes removing excess material from the layer surfaces 726, 728. For example, the excess material (e.g., from the dielectric material 724, the metal layer 735, and/or the non-conductive material 740) can be removed by at least one of etching, grinding, etc. of the layer surfaces 726, 728.

At block 822, the example method 800 includes applying and patterning the example photoresist layer(s) 741 on one(s) of the layer surfaces 726, 728. In some examples, an example pattern can be provided on the photoresist layer(s) 741 using photolithography to produce the openings 743 in the photoresist layer(s) 741 that expose the grounding members 738A, 738B, 738C, 738D and/or the signal PTH 734.

At block 824, the example method 800 includes fabricating one or more example pads on one(s) of the layer surfaces 726, 728. For example, the first contact pad 742A and the first and second via pads 744A, 744B are fabricated on the first layer surface 726, and the second contact pad 742B and the third and fourth via pads 744C, 744D are fabricated on the second layer surface 728. In such examples, the first and second contact pads 742A, 742B are coupled to the signal PTH 732, and the via pads 744A, 744B, 744C, 744D are coupled to respective ones of the grounding members 738A, 738, 738C, 738D.

At block 826, the example method 800 includes removing the photoresist layer(s) 741. For example, the photoresist layer(s) 741 can be removed from the respective first layer surface 726 and/or the second layer surface 728. In some examples, one or more additional dielectric layers and/or conductive layers can be fabricated on the first dielectric layer 716 and/or the second dielectric layer 718 to complete fabrication of the package substrate (e.g., the package substrate 110 of FIG. 1 and/or the package substrate 600 of FIG. 6).

At block 828, the example method 800 includes determining whether an additional build-up layer is to be added. In response to determining that another build-up layer is to be added (e.g., block 828 returns a result of YES), the process returns to block 812. Alternatively, in response to determining that no additional build-up layer is to be added (e.g., block 828 returns a result of NO), the process ends.

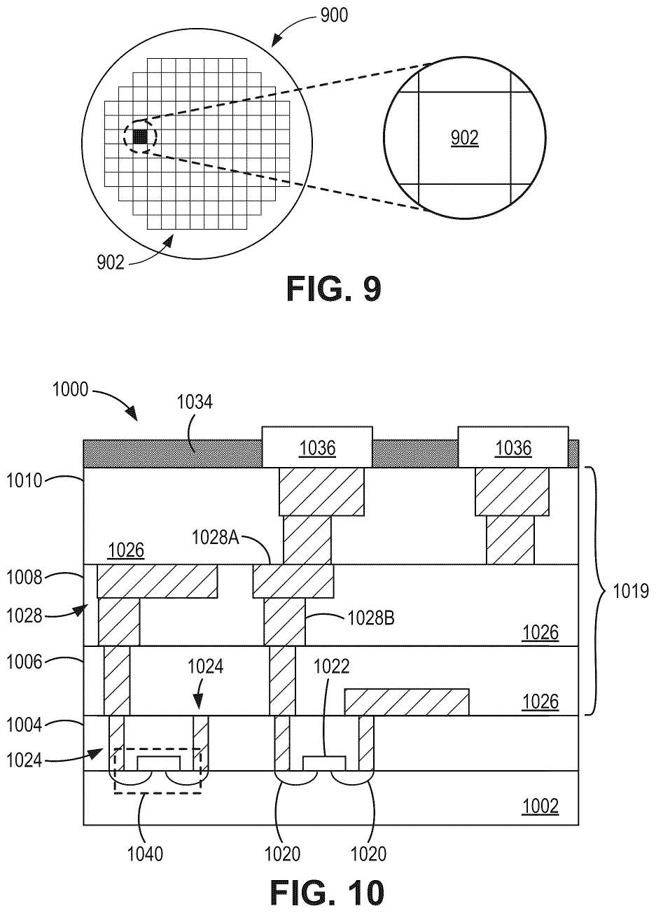

The example grounding PTHs (e.g., the grounding PTH 200 of FIGS. 2, 3, 4, and/or 6 and/or the grounding PTH 714 of FIGS. 7A, 7B, 7C, 7D, 7E, 7F, 7G, and/or 7I) disclosed herein may be included in any suitable electronic component. FIGS. 9-12 illustrate various examples of apparatus that may include or be included in example grounding PTHs (e.g., the grounding PTH 200 of FIGS. 2, 3, 4, and/or 6 and/or the grounding PTH 714 of FIGS. 7A, 7B, 7C, 7D, 7E, 7F, 7G, and/or 7I) disclosed herein.

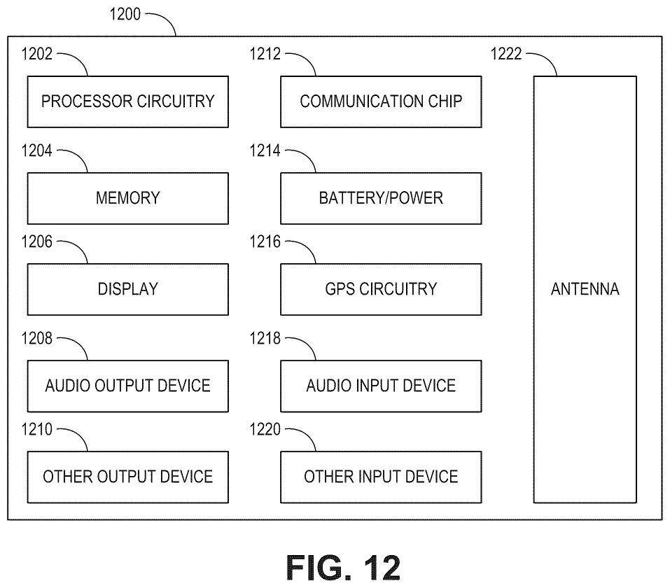

FIG. 9 is a top view of a wafer 900 and dies 902 that may be included in an IC package whose substrate includes one or more grounding PTHs (e.g., the grounding PTH 200 of FIGS. 2, 3, 4, and/or 6 and/or the grounding PTH 714 of FIGS. 7A, 7B, 7C, 7D, 7E, 7F, 7G, and/or 7I) in accordance with any of the examples disclosed herein. The wafer 900 includes semiconductor material and one or more dies 902 having circuitry. Each of the dies 902 may be a repeating unit of a semiconductor product. After the fabrication of the semiconductor product is complete, the wafer 900 may undergo a singulation process in which the dies 902 are separated from one another to provide discrete “chips.” The die 902 includes one or more transistors (e.g., some of the transistors 1040 of FIG. 10, discussed below), supporting circuitry to route electrical signals to the transistors, passive components (e.g., traces, resistors, capacitors, inductors, and/or other circuitry), and/or any other components. In some examples, the die 902 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 902. For example, a memory array of multiple memory circuits may be formed on a same die 902 as programmable circuitry (e.g., the processor circuitry 1202 of FIG. 12) and/or other logic circuitry. Such memory may store information for use by the programmable circuitry. The example IC package 100 disclosed herein may be manufactured using a die-to-wafer assembly technique in which some dies are attached to a wafer 900 that includes others of the dies, and the wafer 900 is subsequently singulated.

FIG. 10 is a cross-sectional side view of an IC device 1000 that may be included in an IC package whose substrate includes one or more grounding PTHs (e.g., the grounding PTH 200 of FIGS. 2, 3, 4, and/or 6 and/or the grounding PTH 714 of FIGS. 7A, 7B, 7C, 7D, 7E, 7F, 7G, and/or 7I) in accordance with any of the examples disclosed herein. One or more of the IC devices 1000 may be included in one or more dies 902 (FIG. 9). The IC device 1000 may be formed on a die substrate 1002 (e.g., the wafer 900 of FIG. 9) and may be included in a die (e.g., the die 902 of FIG. 9). The die substrate 1002 may be a semiconductor substrate including semiconductor materials including, for example, n-type or p-type materials systems (or a combination of both). The die substrate 1002 may include, for example, a crystalline substrate formed using a bulk silicon or a silicon-on-insulator (SOI) substructure. In some examples, the die substrate 1002 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an IC device 1000 may be used. The die substrate 1002 may be part of a singulated die (e.g., the dies 902 of FIG. 9) or a wafer (e.g., the wafer 900 of FIG. 9).

The IC device 1000 may include one or more device layers 1004 disposed on and/or above the die substrate 1002. The device layer 1004 may include features of one or more transistors 1040 (e.g., metal oxide semiconductor field-effect transistors (MOSFETs)) formed on the die substrate 1002. The device layer 1004 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1040 may include a gate 1022 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1040 along the source-channel-drain direction, the gate electrode may include a U-shaped structure that includes a bottom portion substantially parallel to the surface of the die substrate 1002 and two sidewall portions that are substantially perpendicular to the top surface of the die substrate 1002. In other examples, at least one of the metal layers that form the gate electrode may be a planar layer that is substantially parallel to the top surface of the die substrate 1002 and does not include sidewall portions substantially perpendicular to the top surface of the die substrate 1002. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of corresponding transistor(s) 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1020 may be formed using one or more alternate semiconductor materials such as germanium or a group III-V material or alloy. In further examples, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the IC device 1000.

The interconnect structures 1028 may be arranged within the interconnect layers 1006-1010 to route electrical signals according to a wide variety of designs (in particular, the arrangement is not limited to the particular configuration of interconnect structures 1028 depicted in FIG. 10). Although a particular number of interconnect layers 1006-1010 is depicted in FIG. 10, examples of the present disclosure include IC devices having more or fewer interconnect layers than depicted.

In some examples, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and/or out of the page from the perspective of FIG. 10. The vias 1028b may be arranged to route electrical signals in a direction of a plane that is substantially perpendicular to the surface of the die substrate 1002 upon which the device layer 1004 is formed. In some examples, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some examples, the dielectric material 1026 disposed between the interconnect structures 1028 in different ones of the interconnect layers 1006-1010 may have different compositions; in other examples, the composition of the dielectric material 1026 between different interconnect layers 1006-1010 may be the same.

A first interconnect layer 1006 (referred to as Metal 1 or “M1”) may be formed directly on the device layer 1004. In some examples, the first interconnect layer 1006 may include lines 1028a and/or vias 1028b, as shown. The lines 1028a of the first interconnect layer 1006 may be coupled with contacts (e.g., the S/D contacts 1024) of the device layer 1004.

A second interconnect layer 1008 (referred to as Metal 2 or “M2”) may be formed directly on the first interconnect layer 1006. In some examples, the second interconnect layer 1008 may include vias 1028b to couple the lines 1028a of the second interconnect layer 1008 with the lines 1028a of the first interconnect layer 1006. Although the lines 1028a and the vias 1028b are structurally delineated with a line within each interconnect layer (e.g., within the second interconnect layer 1008) for the sake of clarity, the lines 1028a and the vias 1028b may be structurally and/or materially contiguous (e.g., simultaneously filled during a dual-damascene process) in some examples.

A third interconnect layer 1010 (referred to as Metal 3 or “M3”) (and additional interconnect layers, as desired) may be formed in succession on the second interconnect layer 1008 according to similar techniques and/or configurations described in connection with the second interconnect layer 1008 or the first interconnect layer 1006. In some examples, the interconnect layers that are “higher up” in the metallization stack 1019 in the IC device 1000 (i.e., further away from the device layer 1004) may be thicker.

The IC device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to other external devices. For example, solder bonds may be formed on the one or more conductive contacts 1036 to mechanically and/or electrically couple a chip including the IC device 1000 with another component (e.g., a circuit board). The IC device 1000 may include additional or alternate structures to route the electrical signals from the interconnect layers 1006-1010; for example, the conductive contacts 1036 may include other analogous features (e.g., posts) that route the electrical signals to external components.

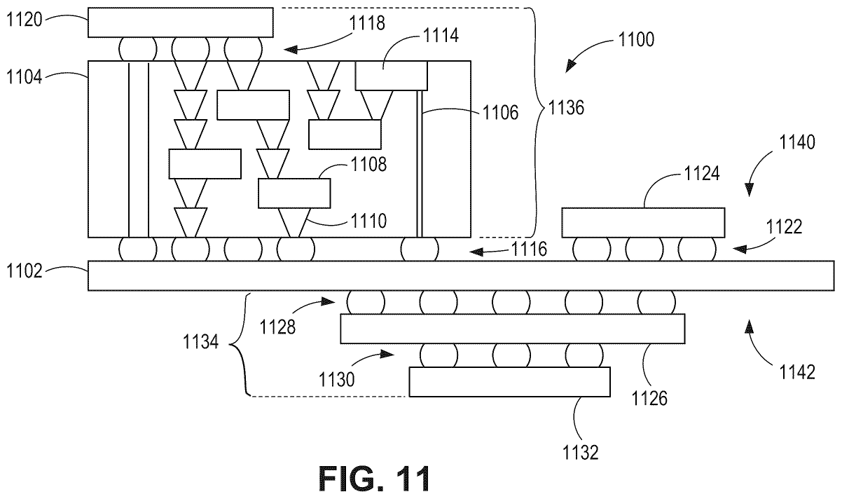

FIG. 11 is a cross-sectional side view of an IC device assembly 1100 that may include the example grounding PTHs (e.g., the grounding PTH 200 of FIGS. 2, 3, 4, and/or 6 and/or the grounding PTH 714 of FIGS. 7A, 7B, 7C, 7D, 7E, 7F, 7G, and/or 7I) disclosed herein. The IC device assembly 1100 includes a number of components disposed on a circuit board 1102 (which may be, for example, a motherboard). The IC device assembly 1100 includes components disposed on a first face 1140 of the circuit board 1102 and an opposing second face 1142 of the circuit board 1102; generally, components may be disposed on one or both faces 1140 and 1142. Any of the IC packages discussed below with reference to the IC device assembly 1100 may take the form of the example IC package 100 of FIG. 1.

In some examples, the circuit board 1102 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1102. In other examples, the circuit board 1102 may be a non-PCB substrate.

The IC device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), male and female portions of a socket, an adhesive, an underfill material, and/or any other suitable electrical and/or mechanical coupling structure.

The package-on-interposer structure 1136 may include an IC package 1120 coupled to an interposer 1104 by coupling components 1118. The coupling components 1118 may take any suitable form for the application, such as the forms discussed above with reference to the coupling components 1116. Although a single IC package 1120 is shown in FIG. 11, multiple IC packages may be coupled to the interposer 1104; indeed, additional interposers may be coupled to the interposer 1104. The interposer 1104 may provide an intervening substrate used to bridge the circuit board 1102 and the IC package 1120. The IC package 1120 may be or include, for example, a die (the die 902 of FIG. 9), an IC device (e.g., the IC device 1000 of FIG. 10), or any other suitable component. Generally, the interposer 1104 may spread a connection to a wider pitch or reroute a connection to a different connection. For example, the interposer 1104 may couple the IC package 1120 (e.g., a die) to a set of BGA conductive contacts of the coupling components 1116 for coupling to the circuit board 1102. In the example illustrated in FIG. 11, the IC package 1120 and the circuit board 1102 are attached to opposing sides of the interposer 1104; in other examples, the IC package 1120 and the circuit board 1102 may be attached to a same side of the interposer 1104. In some examples, three or more components may be interconnected by way of the interposer 1104. In some examples, the interposer 1104 can include a High Density Interconnection (HDI) substrate. In some examples, the interposer 1104 can include one or more of the example grounding PTHs (e.g., the grounding PTH 200 of FIGS. 2, 3, 4, and/or 6 and/or the grounding PTH 714 of FIGS. 7A, 7B, 7C, 7D, 7E, 7F, 7G, and/or 7I) disclosed herein.

In some examples, the interposer 1104 may be formed as a PCB, including multiple metal layers separated from one another by layers of dielectric material and interconnected by electrically conductive vias. In some examples, the interposer 1104 may be formed of an epoxy resin, a fiberglass-reinforced epoxy resin, an epoxy resin with inorganic fillers, a ceramic material, or a polymer material such as polyimide. In some examples, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through-silicon vias (TSVs) 1106. The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The IC device assembly 1100 may include an IC package 1124 coupled to the first face 1140 of the circuit board 1102 by coupling components 1122. The coupling components 1122 may take the form of any of the examples discussed above with reference to the coupling components 1116, and the IC package 1124 may take the form of any of the examples discussed above with reference to the IC package 1120.

The IC device assembly 1100 illustrated in FIG. 11 includes a package-on-package structure 1134 coupled to the second face 1142 of the circuit board 1102 by coupling components 1128. The package-on-package structure 1134 may include a first IC package 1126 and a second IC package 1132 coupled together by coupling components 1130 such that the first IC package 1126 is disposed between the circuit board 1102 and the second IC package 1132. The coupling components 1128, 1130 may take the form of any of the examples of the coupling components 1116 discussed above, and the IC packages 1126, 1132 may take the form of any of the examples of the IC package 1120 discussed above. The package-on-package structure 1134 may be configured in accordance with any of the package-on-package structures known in the art.

FIG. 12 is a block diagram of an example electrical device 1200 that may include one or more of the example grounding PTHs (e.g., the grounding PTH 200 of FIGS. 2, 3, 4, and/or 6 and/or the grounding PTH 714 of FIGS. 7A, 7B, 7C, 7D, 7E, 7F, 7G, and/or 7I). For example, any suitable ones of the components of the electrical device 1200 may include one or more of the device assemblies 1100, IC devices 2000, or dies 1902 disclosed herein. A number of components are illustrated in FIG. 12 as included in the electrical device 1200, but any one or more of these components may be omitted or duplicated, as suitable for the application. In some examples, some or all of the components included in the electrical device 1200 may be attached to one or more motherboards. In some examples, some or all of these components are fabricated onto a single system-on-a-chip (SoC) die.

Additionally, in various examples, the electrical device 1200 may not include one or more of the components illustrated in FIG. 12, but the electrical device 1200 may include interface circuitry for coupling to the one or more components. For example, the electrical device 1200 may not include a display 1206, but may include display interface circuitry (e.g., a connector and driver circuitry) to which a display 1206 may be coupled. In another set of examples, the electrical device 1200 may not include an audio input device 1218 (e.g., microphone) or an audio output device 1208 (e.g., a speaker, a headset, earbuds, etc.), but may include audio input or output device interface circuitry (e.g., connectors and supporting circuitry) to which an audio input device 1218 or audio output device 1208 may be coupled.

The electrical device 1200 may include programmable circuitry 1202 (e.g., one or more processing devices). The programmable circuitry 1202 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1200 may include a memory 1204, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1204 may include memory that shares a die with the programmable circuitry 1202. This memory may be used as cache memory and may include embedded dynamic random access memory (eDRAM) or spin transfer torque magnetic random access memory (STT-MRAM).

In some examples, the electrical device 1200 may include a communication chip 1212 (e.g., one or more communication chips). For example, the communication chip 1212 may be configured for managing wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1212 may operate in accordance with other wireless protocols in other examples. The electrical device 1200 may include an antenna 1222 to facilitate wireless communications and/or to receive other wireless communications (such as AM or FM radio transmissions).

In some examples, the communication chip 1212 may manage wired communications, such as electrical, optical, or any other suitable communication protocols (e.g., the Ethernet). As noted above, the communication chip 1212 may include multiple communication chips. For instance, a first communication chip 1212 may be dedicated to shorter-range wireless communications such as Wi-Fi or Bluetooth, and a second communication chip 1212 may be dedicated to longer-range wireless communications such as global positioning system (GPS), EDGE, GPRS, CDMA, WiMAX, LTE, EV-DO, or others. In some examples, a first communication chip 1212 may be dedicated to wireless communications, and a second communication chip 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display 1206 (or corresponding interface circuitry, as discussed above). The display 1206 may include any visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any device that generates an audible indicator, such as speakers, headsets, or earbuds.

The electrical device 1200 may include an audio input device 1218 (or corresponding interface circuitry, as discussed above). The audio input device 1218 may include any device that generates a signal representative of a sound, such as microphones, microphone arrays, or digital instruments (e.g., instruments having a musical instrument digital interface (MIDI) output).

The electrical device 1200 may include GPS circuitry 1216. The GPS circuitry 1216 may be in communication with a satellite-based system and may receive a location of the electrical device 1200, as known in the art.

The electrical device 1200 may include any other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include any other input device 1220 (or corresponding interface circuitry, as discussed above). Examples of the other input device 1220 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1200 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that reduce crosstalk in integrated circuit (IC) packages. Examples disclosed herein provide an example grounding PTH in an example package substrate to surround (e.g., encircle, extend continuously around, etc.) one or more example signal vias positioned in the package substrate. In some examples, the grounding PTH is electrically coupled (e.g., via one or more example grounding micro-vias) to an example ground plane of the package substrate to provide a return path for electrical signals to the ground plane. In some examples, by providing the grounding PTH around the signal via(s), electrical signals passing through the signal via(s) can be shielded from the effects of crosstalk from other signals passing through the package substrate, thereby improving the quality and/or reliability of the electrical signals. Further, by reducing the effects of crosstalk between neighboring signals in a package substrate, the grounding PTH enables signal vias to be positioned closer together (e.g., at a reduced pitch) in the package substrate (e.g., compared to when the grounding PTH is not used). Accordingly, disclosed systems, apparatus, articles of manufacture, and methods improve the efficiency of using a computing device by increasing a number of signal vias that may be included in an example package substrate, thus increasing a signaling bandwidth and/or increasing speed of information travel through the package substrate. Disclosed systems, apparatus, articles of manufacture, and methods are accordingly directed to one or more improvement(s) in the operation of a machine such as a computer or other electronic and/or mechanical device.

Example methods, apparatus, systems, and articles of manufacture to reduce crosstalk in an integrated circuit package are disclosed herein. Further examples and combinations thereof include the following:

Example 1 includes an apparatus, comprising a package substrate, a conductive via extending between first and second surfaces of the package substrate, a metal casing extending between the first and second surfaces, the metal casing surrounding the conductive via, and a dielectric material positioned between the conductive via and the metal casing.

Example 2 includes the apparatus of example 1, wherein the conductive via is a first conductive via, further including a second conductive via extending between the first and second surfaces and surrounded by the metal casing, the second conductive via spaced apart from the first conductive via.

Example 3 includes the apparatus of example 2, wherein a cross-sectional shape of the metal casing includes a first rounded portion and a second rounded portion, the first conductive via positioned in the first rounded portion, the second conductive via positioned in the second rounded portion.

Example 4 includes the apparatus of example 1, further including a grounding micro-via coupled to the metal casing.

Example 5 includes the apparatus of example 4, wherein the conductive via is coupled to a first pad and the grounding micro-via is coupled to a second pad, the first pad in a first metal layer of the package substrate, the grounding micro-via in a second metal layer of the package substrate, the first metal layer different from the second metal layer.

Example 6 includes the apparatus of example 1, wherein the dielectric material is a first dielectric material, the conductive via including a plated through-hole and a second dielectric material positioned in the plated through-hole.

Example 7 includes the apparatus of example 1, wherein the metal casing is defined by a metal wall extending continuously around the conductive via.

Example 8 includes an apparatus comprising a package substrate, a core in the package substrate, a first plated through-hole extending through the core, a second plated through-hole extending through the core, the second plated through-hole extending along an inside of the first plated through-hole, and a dielectric material positioned between the first and second plated through-holes.

Example 9 includes the apparatus of example 8, further including a third plated through-hole extending through the core, the third plated through-hole extending along an inside of the first plated through-hole and spaced apart from the second plated through-hole.

Example 10 includes the apparatus of example 9, wherein a distance between a first center of the second plated through-hole and a second center of the third plated through-hole is 400 micrometers or less.

Example 11 includes the apparatus of example 8, further including a non-conductive polymer positioned in the second plated through-hole.

Example 12 includes the apparatus of example 8, wherein a distance between an inner surface of the first plated through-hole and an outer surface of the second plated through-hole is 150 micrometers or less.

Example 13 includes the apparatus of example 8, wherein the first plated through-hole is coaxially aligned with the second plated through-hole.

Example 14 includes the apparatus of example 8, further including a grounding micro-via in a dielectric layer of the package substrate, the grounding micro-via coupled to the first plated through-hole.

Example 15 includes the apparatus of example 8, wherein a second end of the second plated through-hole is farther away from a surface of the core than a first end of the first plated through-hole is from the surface of the core.

Example 16 includes a method comprising providing a cavity in a substrate core, the cavity extending through the substrate core, providing first metallic plating on sidewalls of the cavity to produce a casing, providing dielectric material in the casing, providing a through-hole in the dielectric material, the through-hole extending through the dielectric material, and providing second metallic plating in the through-hole to produce a plated through-hole.

Example 17 includes the method of example 16, further including providing a non-conductive material in the plated through-hole.

Example 18 includes the method of example 16, further including providing the cavity by providing a first circular cavity and a second circular cavity in the substrate core, the first circular cavity overlapping with the second circular cavity.

Example 19 includes the method of example 16, wherein the plated through-hole is a first plated through-hole, further including providing a second plated through-hole in the dielectric material, the second plated through-hole spaced apart from the first plated through-hole.

Example 20 includes the method of example 16, further including fabricating a dielectric layer on at least one of a first surface of the substrate core or a second surface of the substrate core, and providing a grounding micro-via in the dielectric layer, the grounding micro-via electrically coupled to the casing.

Example 21 includes the method of example 20, further including providing a first pad and a second pad on the dielectric layer, the first pad coupled to the plated through-hole, the second pad coupled to the grounding micro-via.

Example 22 includes an apparatus comprising a package substrate, a semiconductor die mounted to the package substrate, means for transmitting a signal through a core of the package substrate, and means for electrically shielding the means for transmitting, the means for electrically shielding to encircle the means for transmitting.

Example 23 includes the apparatus of example 22, further including means for grounding the means for electrically shielding.

Example 24 includes the apparatus of example 22, wherein the means for transmitting is a first means for transmitting, the apparatus further including a second means for transmitting a signal through the core of the package substrate, the means for electrically shielding to encircle both the first and second means for transmitting.

Example 25 includes the apparatus of example 22, further including at least one of a keyboard or a display operatively coupled to the semiconductor die.

Example 26 includes the apparatus of example 22, wherein the means for transmitting is coaxially aligned with the means for electrically shielding.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus, comprising:
a package substrate;
a conductive via extending between first and second surfaces of the package substrate;
a metal casing extending between the first and second surfaces, the metal casing surrounding the conductive via; and
a dielectric material positioned between the conductive via and the metal casing.

2. The apparatus of claim 1, wherein the conductive via is a first conductive via, further including a second conductive via extending between the first and second surfaces and surrounded by the metal casing, the second conductive via spaced apart from the first conductive via.

3. The apparatus of claim 2, wherein a cross-sectional shape of the metal casing includes a first rounded portion and a second rounded portion, the first conductive via positioned in the first rounded portion, the second conductive via positioned in the second rounded portion.

4. The apparatus of claim 1, further including a grounding micro-via coupled to the metal casing.

5. The apparatus of claim 4, wherein the conductive via is coupled to a first pad and the grounding micro-via is coupled to a second pad, the first pad in a first metal layer of the package substrate, the grounding micro-via in a second metal layer of the package substrate, the first metal layer different from the second metal layer.

6. The apparatus of claim 1, wherein the dielectric material is a first dielectric material, the conductive via including a plated through-hole and a second dielectric material positioned in the plated through-hole.

7. The apparatus of claim 1, wherein the metal casing is defined by a metal wall extending continuously around the conductive via.

8. An apparatus comprising:
a package substrate;
a core in the package substrate;
a first plated through-hole extending through the core;
a second plated through-hole extending through the core, the second plated through-hole extending along an inside of the first plated through-hole; and
a dielectric material positioned between the first and second plated through-holes.

9. The apparatus of claim 8, further including a third plated through-hole extending through the core, the third plated through-hole extending along an inside of the first plated through-hole and spaced apart from the second plated through-hole.

10. The apparatus of claim 9, wherein a distance between a first center of the second plated through-hole and a second center of the third plated through-hole is 400 micrometers or less.

11. The apparatus of claim 8, further including a non-conductive polymer positioned in the second plated through-hole.

12. The apparatus of claim 8, wherein a distance between an inner surface of the first plated through-hole and an outer surface of the second plated through-hole is 150 micrometers or less.

13. The apparatus of claim 8, wherein the first plated through-hole is coaxially aligned with the second plated through-hole.

14. The apparatus of claim 8, further including a grounding micro-via in a dielectric layer of the package substrate, the grounding micro-via coupled to the first plated through-hole.

15. The apparatus of claim 8, wherein a second end of the second plated through-hole is farther away from a surface of the core than a first end of the first plated through-hole is from the surface of the core.

16. A method comprising:
providing a cavity in a substrate core, the cavity extending through the substrate core;
providing first metallic plating on sidewalls of the cavity to produce a casing;
providing dielectric material in the casing;
providing a through-hole in the dielectric material, the through-hole extending through the dielectric material; and
providing second metallic plating in the through-hole to produce a plated through-hole.

17. The method of claim 16, further including providing a non-conductive material in the plated through-hole.

18. The method of claim 16, further including providing the cavity by providing a first circular cavity and a second circular cavity in the substrate core, the first circular cavity overlapping with the second circular cavity.

19. The method of claim 16, wherein the plated through-hole is a first plated through-hole, further including providing a second plated through-hole in the dielectric material, the second plated through-hole spaced apart from the first plated through-hole.

20. The method of claim 16, further including:
fabricating a dielectric layer on at least one of a first surface of the substrate core or a second surface of the substrate core; and
providing a grounding micro-via in the dielectric layer, the grounding micro-via electrically coupled to the casing.
